(19) United States
(12) Patent Application Publication
(10) Pub. No.: US 2006/0286808 A1
(43) Pub. Date: Dec. 21, 2006

(54) System and method of processing substrates using sonic energy having cavitation control

(76) Inventor: Ismail Kashkoush, Orefield, PA (US)

Correspondence Address: WOLF, BLOCK, SCHORR & SOLIS-COHEN LLP, 1650 ARCH STREET, 22ND FLOOR, PHILADELPHIA, PA, 19103-2334, US

(21) Appl. No.: 11/454,447

(22) Filed: Jun. 15, 2006

Related U.S. Application Data
(60) Provisional application No. 60/690,586, filed on Jun. 15, 2005.

(51) Int. Cl. B08B 3/00; H01L 21/302

(52) U.S. Cl. 438/745; 134/109

(57) ABSTRACT

A system and method for the acoustic-assisted processing of a substrate, such as a semiconductor wafer, that reduces and/or eliminates damage. The invention suppresses cavitation and pressure effects within the cleaning liquid that may damage devices on the wafer by maintaining the liquid under a constant positive pressure. In one aspect, the invention is a method of processing a substrate comprising: a) supporting a substrate; b) applying a film of liquid to at least one surface of the substrate; c) positioning a transmitter so that at least a portion of the transmitter is in contact with the film of liquid, the transmitter operably coupled to a transducer; d) generating acoustical energy with the transducer; and e) transmitting the acoustical energy to the film of liquid via the transmitter so that the liquid is under only positive pressure during application of the acoustical energy.

### CROSS-REFERENCE TO RELATED APPLCIATIONS

The present application claims the benefit of U.S. Provisional Patent Application 60/690,586, filed Jun. 15, 2005, the entirety of which is hereby incorporated by reference.

### FIELD OF THE INVENTION

The present invention relates generally to the field of processing substrates with acoustical energy, and specifically to the field of processing substrates using acoustical energy that eliminates and/or reduces damage to the substrate by controlling cavitation forces within a processing liquid.

### BACKGROUND OF THE INVENTION

In the field of semiconductor manufacturing, it has been recognized since the beginning of the industry that removing particles from semiconductor wafers during the manufacturing process is a critical requirement to producing quality profitable wafers. While many different systems and methods have been developed over the years to remove particles from semiconductor wafers, many of these systems and methods are undesirable because they damage the wafers. Thus, the removal of particles from wafers, which is often measured in terms of the particle removal efficiency (“PRE”), must be balanced against the amount of damage caused to the wafers by the cleaning method and/or system. It is therefore desirable for a cleaning method or system to be able to break particles free from the delicate semiconductor wafer without resulting in damage to the devices on the wafer surface.

Existing techniques for freeing the particles from the surface of a semiconductor wafer utilize a combination of chemical and mechanical processes. One typical cleaning chemistry used in the art is standard clean 1 (“SC1”), which is a mixture of ammonium hydroxide, hydrogen peroxide, and water. SC1 oxidizes and etches the surface of the wafer. This etching process, known as undercutting, reduces the physical contact area of the wafer surface to which the particle is bound, thus facilitating ease of removal. However, a mechanical process is still required to actually remove the particle from the wafer surface.

For larger particles and for larger devices, scrubbers have historically been used to physically brush the particle off the surface of the wafer. However, as devices shrank in size, scrubbers and other forms of physical cleaning became inadequate because their physical contact with the wafers began to cause catastrophic damage to the smaller/miniaturized devices.

Recently, the application of sonic/acoustical energy to the wafers during chemical processing has replaced physical scrubbing to effectuate particle removal. The acoustical energy used in substrate processing is generated via a source of acoustical energy, which typically comprises a transducer which is made of piezoelectric crystal. In operation, the transducer is coupled to a power source (i.e. a source of electrical energy). An electrical energy signal (i.e. electricity) is supplied to the transducer. The transducer converts this electrical energy signal into vibrational mechanical energy (i.e. sonic/acoustical energy) which is then transmitted to the substrate(s) being processed. Characteristics of the electrical energy signal, which is typically in a sinusoidal waveform, supplied to the transducer from the power source dictate the characteristics of the acoustical energy generated by the transducer. For example, increasing the frequency and/or power of the electrical energy signal will increase the frequency and/or power of the acoustical energy being generated by the transducer.

Recently, wafer cleaning utilizing acoustical energy has become the most effective method of particle removal in semiconductor wet process applications. Acoustical energy has proven to be an effective way to remove particles, but as with any mechanical process, damage is possible and acoustical cleaning is faced with the same damage issues as traditional physical cleaning methods and apparatus. Moreover, the industry's transition to the below 100 nm devices has shown that these fragile structures are more prone to damage during acoustical assisted processing. As the use of single wafer acoustic processing tools continues to increase, so does the potential for device damage. Because a single semiconductor wafer can be very expensive to manufacture, the damage from acoustical energy that results in a decrease in the device yield of semiconductor devices is extremely undesirable. Thus, semiconductor device manufacturers expect acoustical processing units to cause little to no harm to these delicate structures.

To improve cleaning and to reduce damage caused to wafers by the application of ascoustical energy, acoustical energy equipment suppliers have implemented some solutions that control the frequency of the acoustical energy, the amplitude of the acoustical energy, and/or the angles at which the acousticl energy is applied to the wafers. However, even with these controls, damage is still occurring. The terms “acoustical” and “sonic” are used interchangeably throughout this application.

In single wafer megasonic cleaning systems, the effectiveness of megasonics is typically the most critical part of process reliability because of the short cycle time and close proximity to wafer surface. Mechanisms for particle removal have been theorized as acoustical streaming, pressure forces and/or cavitating bubbles. These theories are discussed in Evaluation of Megasonic Cleaning systems for Particle Removal and Damage, ECS Proc. PV2003 26, pp 145 152 by Vereecke, G. et al. Other key variables that are considered to contribute to a good cleaning system are: the energy level and distribution, frequency, wave form, and energy mode of application. The physical properties of the cleaning solution have also shown to play a key role in the cleaning effectiveness. See e.g., Wu, Yi, et al, Acoustic Property Characterization of a Single Wafer Megasonic Cleaner, ECS Proc., PV 1999 36, pp. 360 366. However, the elimination of damage occurrence is still far from optimal for many device sizes. Therefore, there is an immediate need for innovative techniques to provide damage free acoustical-assisted cleaning applications.

### SUMMARY OF THE INVENTION

It is therefore an object of the present invention to provide a system and method of processing substrates using acoustical energy that reduces and/or eliminates damage to devices on the substrates.

Another object of the present invention to provide a system and method of cleaning substrates using acoustic energy that provides effective particle removal from a substrate while reducing the damage caused to the substrate and/or devices thereon.

Yet another object of the present invention is to provide a system and method of processing and/or cleaning substrates using acoustical energy that minimizes and/or eliminates liquid cavitation.

A still further object of the present invention is to provide a system and method of processing and/or cleaning substrates using acoustical energy that increases the device yield.

Another object is to provide a system and method of processing substrates that improves processing efficiency and/or particle removal.

These and other objects are met by the present invention, which in one aspect is a method of processing a substrate comprising: a) supporting a substrate; b) applying a film of liquid to at least one surface of the substrate; c) positioning a transmitter so that at least a portion of the transmitter is in contact with the film of liquid, the transmitter operably coupled to a transducer; d) generating acoustical energy with the transducer; and e) transmitting the acoustical energy to the film of liquid via the transmitter so that the liquid is under only positive pressure during application of the acoustical energy.

Most preferably, the film of liquid is not subjected to a negative pressure during the application of the acoustical energy. By ensuring that the film of liquid is under only positive pressure during the entire acoustical energy application cycle, cavitation and/or unwanted pressure forces within the liquid are suppressed.

In one embodiment of the invention, the acoustical energy has a substantially sinusoidal waveform having a peak amplitude. This peak amplitude corresponds to a peak pressure force that is exerted on the film of liquid during the acoustic energy application cycle. Because a sinusoidal waveform has a repetitive negative and positive aspect, the peak pressure force is applied as both a negative and positive force between the peak negative pressure and the peak positive pressure. Thus, the film of liquid experiences repetitive negative and positive pressure cycles). One way in which the film of liquid can be maintained under constant positive pressure during the entire acoustical energy application cycle is to pressurize the process chamber in which the substrate is located to a pressure that is greater than the peak pressure exerted on the film by the acoustical energy.

In this embodiment, the invention will preferably further comprise the steps of: supporting the substrate in the process chamber in a substantially horizontal orientation; and creating a gaseous atmosphere in the process chamber having a pressure that is maintained above the peak pressure exerted on the film of liquid during application of the acoustical energy.

In another embodiment, the invention may further comprise creating a gaseous atmosphere in the process chamber having a positive pressure that is greater than or equal to an absolute value of a maximum negative pressure exerted on the film of liquid by the acoustical energy. Most preferably, the gaseous atmosphere is maintained at this positive pressure during the entirety of the acoustical energy application cycle.

In an alternative embodiment, the film of liquid can be maintained under positive pressure by creating a plurality of base acoustical signals in the transmitter concurrently so as to form a combined acoustical signal, wherein the characteristics of the base acoustical signals are controlled so that the combined acoustical signal always has a positive amplitude. This can be achieved by the utilization of proper phase shifting, frequency variation, and/or amplitude variation of the base acoustical signals.

The acoustical energy is preferably megasonic energy within the range of 1 to 20 MHz. The transmitter preferably comprises an elongate forward portion that is in contact with the film of liquid or an elongated edge that is in contact with the film of liquid. More preferably, the transmitter is positioned close to but spaced from the surface of the substrate upon which the film of liquid is applied. The positive pressure is preferably above atmospheric pressure.

In another aspect, the invention is a method of processing a substrate comprising: a) supporting a substrate in a substantially horizontal orientation in a process chamber; b) applying a film of liquid to at least one surface of the substrate; c) positioning a transmitter so that at least a portion of the transmitter is in contact with the film of liquid, the transmitter operably coupled to a transducer; d) creating a gaseous atmosphere in the process chamber having a pressure; e) generating acoustical energy with the transducer having a substantially sinusoidal waveform; f) transmitting the acoustical energy to the film of liquid via the transmitter; g) determining a peak pressure exerted on the film of liquid that corresponds to a peak amplitude of the acoustical energy; and wherein the pressure of the gaseous atmosphere is maintained above the peak pressure during the entirety of step f). As with the first embodiment of the invention, the film of liquid is preferably not subjected to a negative pressure during application of the acoustic energy to the substrate.

In yet another aspect, the invention can be a system for processing a substrate comprising: a process chamber having a gaseous atmosphere; a support for supporting a substrate in a substantially horizontal orientation within the gaseous atmosphere of the process chamber; means for applying a film of liquid to a surface of a substrate positioned on the support; a transmitter adapted to be positioned in contact with the film of liquid applied to the surface of the substrate; a transducer operably coupled to the transmitter and adapted to generate acoustical energy having a sinusoidal waveform having a peak amplitude, the peak amplitude corresponding to a peak pressure exerted to the film of liquid; and means for pressurizing the gaseous atmosphere to a pressure that is greater than the peak pressure.

### BRIEF DESCRIPTION OF THE DRAWINGS

FIG. 1 is a schematic of a substrate cleaning system according to one embodiment of the invention.

FIG. 2 is a schematic of a the sinusoidal pressure forced exerted on the film of liquid during the acoustical energy application cycle according to prior art systems.

FIG. 3 is a schematic of a the sinusoidal pressure forced exerted on the film of liquid during the acoustical energy application cycle according to an embodiment of the present invention.

FIG. 4 is a schematic of the transmitter of FIG. 1 coupled to the film of liquid according to an embodiment of the invention.

### DETAILED DESCRIPTION OF THE DRAWINGS

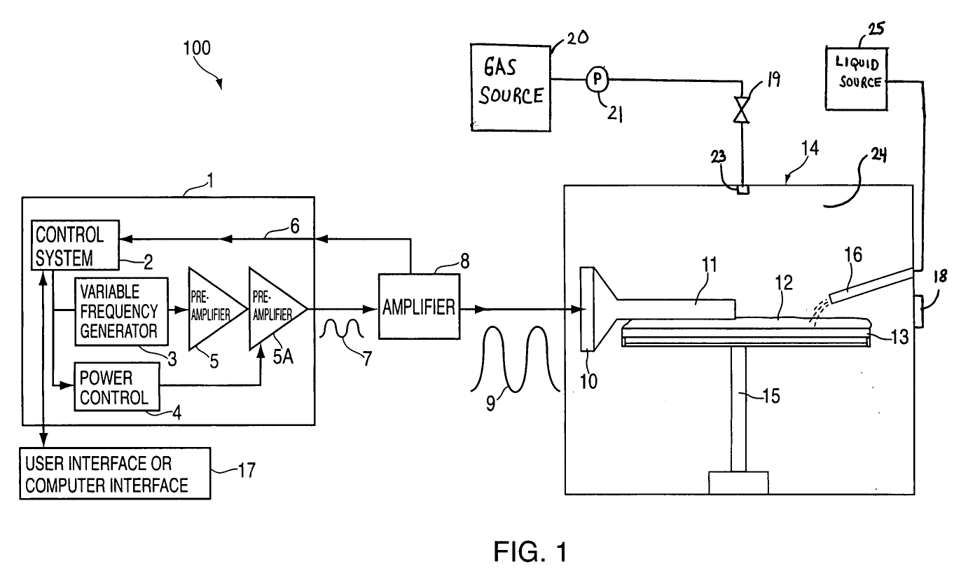

FIG. 1. is a cleaning system 100 according to one embodiment of the present invention. The cleaning system 100 utilizes sonic energy to effectuate the cleaning of a substrate 13. The invention can also be applied to the manufacture of raw wafers, lead frames, medical devices, disks and heads, flat panel displays, microelectronic masks, and other applications requiring levels of cleanliness. The cleaning system 100 is designed to clean substrates, such as semiconductor wafers, with acoustical/sonic energy, which is most preferably in the megaosnic range.

The cleaning system 100 comprises a controller 1, an amplifier 8, a transducer 10, a transmitter 11, a process chamber 14, a support 15, a nozzle 16, a source of gas 20, a source of liquid 25, and a user interface 17. The controller 1 comprises a control system 2, a variable frequency generator 3, a power control unit 4, a pre-amplifier 5, and an attenuator 5A. All of the components of the controller 1 are electrically and operably coupled as illustrated in FIG. 1. The user interface 17 is operbaly coupled to the controller 1 via the control system 2. The amplifier 8 is operbaly coupled to the controller 1 via the attenuator 5A in order to receive a base electrical signal 7. The amplifier 8 is also coupled to the control system 2 in order to transmit data representing forward/reflected power feedback.

The controller 1 is responsible for generating a base electrical signal 7 via the variable frequency generator 3. During a substrate cleaning operation, a user activates the cleaning system 100 by inputting an activation command into the user interface 17. The activation command may include imported process parameters or may be identifiable by the controller 1 so that stored process parameters are retrieved from a memory device.

The activation command is transmitted to the control system 2 as an activation signal. Upon the control system 2 receiving the activation signal, the control system 2 turns on the variable frequency generator 3, thereby creating a base electrical signal 7. The variable frequency generator 3 can be a Direct Digital Synthesis Chip (DDS Chip). Other methods and hardware of frequency generation are also available, including an independent frequency generator.

The base electrical signal 7 is then transmitted through the pre-amplifier 5 and the attenuator 5A to the amplifier 8. The pre-amplifier 5 and the attenuator 5A provide some fine control over the amplitude of the base electrical signal 7. The base electrical signal 7 is created having a desired frequency. The variable frequency generator 3 can vary the frequency of the base electrical signal during its creation if desired. This frequency variation can include sweeping or jumping.

The amplifier 8 is used to increase the amplitude (i.e. the power level) of the base electrical signal 7 to a desired value, thereby converting the base electrical signal 7 into an output electrical signal 9. The frequency of the output electrical signal 9 corresponds to the frequency (whether variable or steady) of the base electrical signal 7 at the desired power level. The output electrical signal 9 is transmitted to the transducer 10 via the appropriate electrical connection. The transducer 10 converts the output electrical signal 9 to corresponding acoustical energy having the same frequency. This acoustical energy is then transmitted via the transmitter 11 to a film 12 of cleaning fluid which is formed on the top planere surface of the substrate 13. The film 12 of liquid is supplied by the nozzle 16 and acts as a coupling layer that thransmits the acoustical energy to the substrate 13. It is preferred that the device side of the substrate 13 be the side to which the transmitter 11 is coupled via the film 12 of cleaning liquid. However, the invention is not so limited

The controller 1 is responsible for monitoring and controlling the power level of the output electrical signal 9 delivered to the transducer 10. Tight control of the power level of the output electrical signal 9 is important to prevent damage to the substrate 13 and the equipment itself. The controller 1 has various methods to control the power level of the output electrical signal 9 including: (1) controlling the amplitude output of the frequency generator itself (DDS chip); (2) providing an analog control signal to control the gain of the pre-amplifier 5 for the electrical signal; (3) providing an analog signal to the attenuator SA (the pre-amplifier 5 typically introduces a fixed gain before the attenuator SA); (4) providing an analog signal to an attenuator within the amplifier 8; and/or (5) providing an analog signal to the amplifier 8 to adjust the amplifier gain. Preferably, a combination of methods (1) and (3) is used.

The controller 1 monitors the forward and reflected power measurements for feedback to control the power via line 6. This feedback can be supplied by the amplifier 8 via line 6 or from an external Directional Coupler and/or independent voltage and current sensors. The controller 1 will control the power level of the output electrical signal 9 to ensure that it does not exceed a target value in order to prevent potential damage to the substrate 13. It is preferred to use a directional coupler incorporated into the amplifier 8 for making these measurements.

The amplifier 8 faithfully reproduces the base electrical signal 7 with a higher power capacity as the output electrical signal 9. The amplifier 8 amplifies the base electrical signal 7 (i.e., converts the base electrical signal 7 into the output electrical signal 9) while minimizing the addition of noise or spikes (i.e., harmonic distortion and spurious content) to the output electrical signal 9.

The amplifier 8 can be a class A or class AB amplifier, such as an AR Kalmus 25A250AM2 amplifier. The amplifier 8 has an internal amplifier brick having a high gain and has a front end attenuator SA. The amplifier 8 should be selected so that clean output electrical signals can be produced up to at least 25 Watts, and preferably higher. The signal generator 3 can be an HP3312A Arbitrary Waveform Generator or the like.

The process chamber 14 is preferably an enclosed chamber capable of being pressurized above atmospheric pressure. The process chamber 14 is hermetically sealable so as to be capable of maintaining a pressurized gaseous atmosphere 24. A slit valve 18 is provided to facilitate the loading and unloading of substrates 12 from the process chamber 14 while maintaining pressurization.

A gas source 20 and a liquid source 25 are operably and fluidly coupled to the process chamber 14. More specifically, the gas source is operably and fluidly coupled to the gas inlet 23 while the liquid source 25 is operably and fluidly coupled to the nozzle 16. A valve 19 and a pump 21 are provided on the gas supply line to facilitate the pressurized supply of gas to the process chamber 14 as needed. The nozzle 16 is positioned above support 13 so that a film 12 of liquid can be supplied to the top surface of substrate 13 when the substrate 13 is located on the support 15.

The support 15 is designed to support the substrate 13 in a substantially horizontal orientation within the process chamber 14 during processing. The support 15 is coupled to a motor so that it can rotate, thereby producing relative motion between the substrate 13 and the transmitter 11 so that acoustical energy can be applied to the entirety of the substrate's surface. Alternatively, the relative motion between the substrate 13 can be achieved translating the transmitter 11, pivoting the transmitter 11, or a combination thereof.

The transmitter 11 is provided in contact with the film 12 of liquid so that acoustical energy generated by the transducer 10 can be transmitted to the substrate 13. As such, the film 12 of liquid acts as a coupling fluid. The transmitter 11 is an elongate rod-like transmitter having an elongated forward portion that extends close to but spaced from the substrate 13. The transmitter 11 comprises an elongated bottom edge 111 that contacts the film of cleaning fluid 12 (best shown in FIG. 4). The invention, however, is not limited by the shape and/or orientation of the transmitter. In other embodiments, the transmitter may be pie-shaped or may be oriented at an angle to the substrate's surface. In one embodiment, the elongated edge can be a side edge of a pie-shaped probe device. In another embodiment, the transmitter can be supported at an angle to the substrate 13 so that the tip of the forward elongate portion of the transmitter is in contact with the film 12 of liquid. It is preferred, however, that the transmitter 11 cover less than the entire surface area of the substrate 13, and that the relative movement between the substrate 13 and the transmitter 11 be implemented to achieve full acoustical energy coverage.

The transducer 10 is operably coupled to the rear end of the transmitter 11. The invention, however, is not limited by the shape and/or positioning of the transducer 10. The transducer can be bonded to the transmitter by any means used in the art, such as with epoxy or the like. In one embodiment, the transducer 10 can be a piezoelectric crystal/ceramic. As discussed above, the transducer converts electrical energy into acoustical energy, which is then transmitted by the transmitter 11 to the substrate 13 to effectuate processing, such as particle removal.

As mentions above, it has been discovered that cavitation and/or pressure forces that are created within the film 12 of liquid during the application of acoustical energy may be responsible for damaging semiconductor devices on the substrate 13. Thus, cavitation suppression may be desired to eliminate damage. However, it has traditionally been though that cavitation is required for high PRE. Nonetheless, it has been noticed that the damage may also caused by cavitation collapsing bubbles.

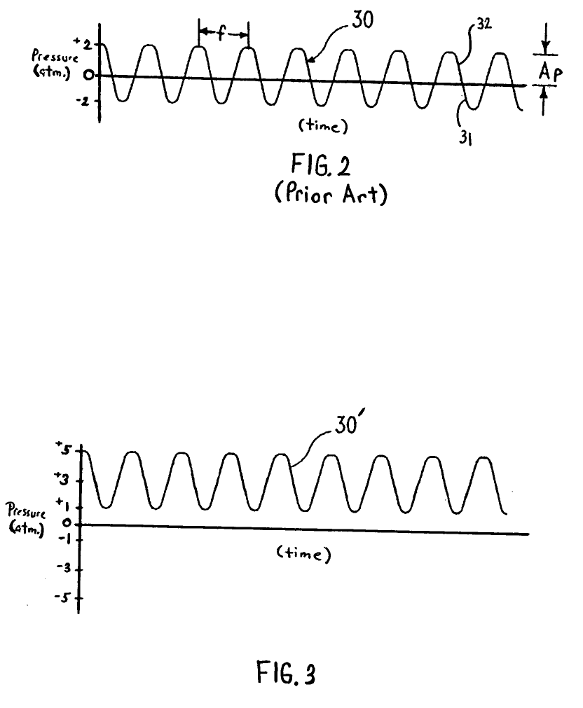

Referring now to FIG. 2, the pressure forces exerted on a film of liquid during existing acoustical energy processing applications is schematically illustrated. In a typical acoustical energy processing application, an electrical signal having a sinusoidal waveform is supplied to a transducer. The transducer converts this electrical energy into acoustical energy having characteristics that correspond to the electrical signal that drives the transducer. Thus, the acoustical energy generated by the transducer will take on a sinusoidal waveform and will have characteristics, such as frequency and amplitude, that correspond to the electrical signal. Because the acoustical energy signal 30 is sinusoidal in nature, it comprises a negative stage 31 and a positive stage 32. The acoustic energy signal 30 also comprises a frequency f and a peak amplitude A_{P}.

As a result of its sinusoidal nature, the acoustical energy signal 30 subjects the film of liquid on the substrate to both negative and positive pressure forces in a repetitive cyclical nature over time. The pressure forces result from the transmitter being moved toward and away from the substrate during vibration. It is believed that this constant transition between negative and positive pressure on the film of liquid causes cavitation and, eventually, damage to the wafer.

It has further been discovered that cavitation and/or pressure effects can be reduced/eliminated if the film of liquid can be statically over pressured during the acoustic energy application cycle. One way in which this can be achieved is by producing a biased acoustic field that exerts only positive pressure on the film of liquid that exceed the cavitation threshold pressure for the liquid. One way in which this can be achieved will now be discussed .

Referring to FIG. 1, a method of cleaning a semiconductor wafer 13 according to an embodiment of the present invention will now be described in relation to system 100. While the invention is described in terms of cleaning, the invention can be used in a wide variety of processing applications. Moreover, the invention is not limited to the processing of semiconductor wafers.

To start, a substrate 13 is inserted into the process chamber 14 via the slit valve 18. The wafer 13 is preferably handled by a robot arm or other means that are well known in the art. The substrate 13 is positioned on and supported by the support 15 in a substantially horizontal orientation, preferably with the device side of the substrate 13 facing up. In other embodiments, the substrate may be supported in a vertical or angled orientation. The support 15 is coupled to a motor so that the substrate 13 can be rotated during processing.

Once the substrate 13 is supported and being rotated within the process chamber 14, a cleaning liquid is applied to the top surface of the substrate 13 via the nozzle 16. In some embodiments, the top surface of the substrate 13 will preferably contain semiconductor devices thereon. The nozzle 16 is operably and fluidly coupled to a source of cleaning liquid 25, such as a reservoir, a mixer, or a bubbler (in the case where the cleaning fluid comprises a dissolved gas). Suitable cleaning liquids include, without limitation, deionized water, gasified deionized water, standard clean 1 (“SC 1”), dilute standard clean 1 (“dSC 1”), dilute ammonia, hydrofluoric acid (“HF”), nitric acid, a mixture of sulfuric acid and a polymer/photoresist stripper, including EKC265, DSP, DSP+, ST22, ST28, ST 255, and ST250. In some embodiments, the cleaning liquid may comprise a dissolved gas, such as ozone or other gases. In other embodiments of the invention, the system can be used for processes other than traditional cleaning, such as photo-resist stripping, etc.

The cleaning liquid is applied to the top surface of the substrate 13 via the nozzle 16 so that a film/layer/meniscus 12 of the liquid forms on the top surface of the substrate 13. The film 12 of liquid forms a fluid coupling between the top surface of the substrate 13 and the elongated bottom edge 111 of the probe transmitter 11 (FIG. 4). Optionally, a second nozzle or other source can be provided to simultaneously supply cleaning liquid to the bottom surface of the substrate 13 if desired. It is preferred that the cleaning liquid be at ambient temperature when applied to the substrate surface.

Once the film 12 of liquid is formed on the top surface of the substrate 13, the controller 1 is activated, thereby creating a base electrical signal 7 which is transmitted to the amplifier 8 for conversion to the output electrical signal 9 as discussed above. The output electrical signal 9 is created having a desired frequency and a desired power level (i.e., an amplitude), which is dictated by user preferences/inputs programmed into the control system 2.

The output electrical signal 9 is transmitted to the transducer 10 for conversion into acoustical energy. The characteristics of the acoustical energy created by the transducer 10, e.g. frequency and amplitude, correspond to the characteristics of the output electrical signal 9 supplied to the transducer 10. The desired frequency of the output electrical signal 9 is preferably chosen so that the sonic energy created by the transducer is within a range of approximately 400 kHz to 20 MHz, and possibly higher. The optimal frequency for substrate cleaning will be dictated by design considerations and will be determined on a case by case basis. Relevant considerations can include, without limitation: (1) the size of the devices on the substrate; (2) the size of the particles desired to be removed; (3) the desired power level; (4) the cleaning fluid being used; and (5) the processing time and temperatures.

The acoustical energy created by the transducer 11 has the sinusoidal waveform characteristics of the electrical signal 9 that drives the transducer. However, in order to eliminate/suppress cavitation within the film 12 of liquid, a gaseous atmosphere 24 is created within the process chamber 14 that is sufficiently under pressure so as to offset the acoustical energy signal so that the film 12 of liquid only experiences positive pressure during the application of the acoustical energy to the substrate 13. The gaseous atmosphere is created by activating pump 21 and opening valve 19, thereby allowing the gas from the gas source 20 to flow into and pressurize the process chamber 14. The gas can be any reactive or non-reactive gas, including without limitation air, ozone, nitrogen, oxygen, or any inert gas.

The pressure at which the gaseous atmosphere 24 is created (and maintained during the acoustic energy application cycle) is chosen so that it is greater than the peak pressure exerted on the film 12 of liquid at the peak amplitude of the acoustic energy signal generated by the transducer 10 (and transmitted via the transmitter 11).

For example, assume that the acoustical energy signal generated by the transducer 10 is the same as that which is shown in FIG. 2. This acoustical energy signal 30 has a peak amplitude A_{P} that corresponds to exerting ± two atmospheres of pressures on the film 12 of liquid in an un-pressurized process chamber. Thus, according to the present invention, the gaseous atmosphere 24 within the process chamber 14 should be created and maintained at a pressure greater than two atmospheres for this scenario.

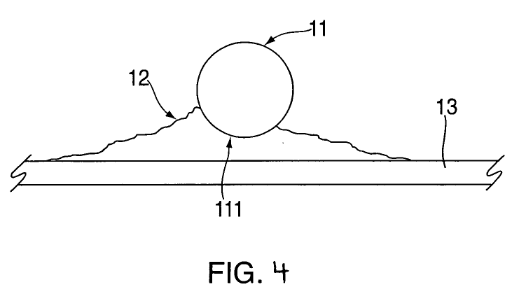

Referring to FIG. 3, if the gaseous atmosphere 24 within the process chamber 14 is maintained at three atmospheres, the pressure exerted on the film 12 of liquid by the acoustic energy signal is offset so as to take on sinusoidal waveform 30′. As can be seen from FIG. 3, pressurizing the gaseous atmosphere 24 results in the film 12 of liquid experiencing only positive pressure, in the range of +one to +five atmospheres. As a result, the film 12 of the liquid does not undergo the repetitive switch from positive to negative pressure effects, thereby suppressing cavitation.

The desired pressure of the gaseous atmosphere 24 for any given situation is dictated by the peak amplitude characteristic of the acoustical energy being transmitted to the film 12 of liquid. For example, at the peak amplitude of the acoustical energy signal a peak pressure (negative and positive) will be exerted on the film 12 of the liquid. As such, in some instances, the desired pressure of the gaseous atmosphere 24 should be greater than the absolute value of the peak negative pressure exerted by the acoustical energy. The pressure values exerted on the film 12 of liquid for any acoustical energy signal can be experimentally determined through the use of pressure sensors and the like. For example, pressure sensors can be positioned below a film of liquid which is also coupled to a transmitter/transducer assembly at the film surface. Preferably, the distance between the pressure sensors and the transmitter is the same as the distance between the transmitter and the substrate to be processed during a cleaning process. The transmitter/transducer assembly is driven by a sinusoidal electrical signal having know characteristics. The pressure readings by the pressure sensors are graphed, thereby rendering a corresponding sinusoidal pressure output of the transmitter. The positive and negative peak pressures experienced by the liquid should have approximately the same absolute value. The desired pressure of the gaseous atmosphere 24 should be greater than this absolute value to ensure that the film 12 of liquid is always under positive pressure during acoustic energy applications.

Once the gaseous atmosphere 24 is properly created having the desired pressure, the energy is transmitted by the transmitter 11 to the film 12 of liquid. The acoustical energy is then transmitted through the film 12 of liquid to the top surface of the substrate 13. The acoustic energy loosens particles on the top surface of the substrate 13 which are then carried away by the centrifugal fluidic motion of the film 12 of liquid. The acoustic energy is applied to the substrate 13 for a predetermined period of time during the continued application of the liquid. Preferably, the predetermined time is within the range of 1 to 300 seconds, is more preferably within the range of 20 to 100 seconds, and is most preferably about 30 to 60 seconds.

In order to reduce and/or eliminate damage to the devices on the top surface of the substrate 13, the film 12 of liquid should be maintained under positive pressure during the entire period of acoustic energy application. At no time should the aggregate pressure be exerted on the film 12 of liquid be negative.

In an alternative embodiment, the film 12 of liquid can be maintained under positive pressure by creating a plurality of base acoustical signals in the transmitter concurrently so as to form a combined acoustical signal that always has a positive amplitude. This can be achieved by the proper phase shifting, frequency variation, and/or amplitude variation. Multiple transducers may have to be used and positioned in different planes to achieve this effect.

With respect to the cleaning liquid used and their properties, the speed of sound and cavitation threshold depends on the fluid properties e.g. density, viscosity, gas content, and impurities. The present invention is a system and method of megasonic processing that yields the highest possible particle removal efficiency (“PRE”) while minimizing or eliminating damage to fragile integrate circuit (“IC”) structures. The present invention is based on the discovery of two new key factors that affectuate particle removal while reducing device damage on the wafer surfaces. These two factors are: (1) high frequency of the megasonic energy; and (2) cavitation control of the coupling fluid.

Alternatively, the presence of high frequency positive pressure pulses will suppress the potential for cavitation nucleation. This may be achieve by utilizing more than on transducer. The invention, in one aspect, can be a megasonic cleaning system that utilizes two transducers (or segments of the same transducer) that are designed and operated such that the liquid is constantly under pressure during the cleaning cycle. The cleaning mechanism will be utilizing the high frequency waves in a cavitation free (or suppressed) liquid.

While a number of embodiments of the current invention have been described and illustrated in detail, various alternatives and modifications will become readily apparent to those skilled in the art without departing from the spirit and scope of the invention.

What is claimed is:

1. A method of processing a substrate comprising:
a) supporting a substrate;
b) applying a film of liquid to at least one surface of the substrate;
c) positioning a transmitter so that at least a portion of the transmitter is in contact with the film of liquid, the transmitter operably coupled to a transducer;
d) generating acoustical energy with the transducer; and
e) transmitting the acoustical energy to the film of liquid via the transmitter so that the liquid is under only positive pressure during application of the acoustical energy.

2. The method of claim 1 wherein the film of liquid is not subjected to a negative pressure during step e).

3. The method of claim 1 further:
wherein step a) comprises supporting a substrate in a process chamber in a substantially horizontal orientation;
wherein the acoustical energy has a substantially sinusoidal waveform having a peak amplitude that corresponds to a peak pressure exerted on the film of liquid; and
creating a gaseous atmosphere in the process chamber having a pressure that is maintained above the peak pressure exerted on the film during step e).

4. The method of claim 1 further comprising creating a gaseous atmosphere in the process chamber having a positive pressure that is greater than or equal to an absolute value of a maximum negative pressure exerted on the film of liquid by the acoustical energy during step e).

5. The method of claim 5 further comprising maintaining the gaseous atmosphere at the positive pressure during the entirety of step e).

6. The method of claim 1 wherein the acoustical energy is megasonic energy.

7. The method of claim 1 wherein the transmitter comprises an elongate forward portion that is in contact with the film of liquid.

8. The method of claim 1 wherein the transmitter comprises an elongated edge that is in contact with the film of liquid.

9. The method of claim 1 wherein the positive pressure is above atmospheric pressure.

10. The method of claim 1 wherein step c) comprises positioning the transmitter close to but spaced from the surface of the substrate upon which the film of liquid is applied.

11. The method of claim 1 further:
wherein the film of liquid is not subjected to a negative pressure during step e);
wherein step a) comprises supporting a substrate in a process chamber in a substantially horizontal orientation;
wherein step c) comprises positioning the transmitter close to but spaced from the surface of the substrate upon which the film of liquid is applied, the transmitter comprising an elongate forward portion that is in contact with the film of liquid;
wherein the acoustical energy has a substantially sinusoidal waveform having a peak amplitude that corresponds to a peak pressure exerted on the film of liquid;
creating a gaseous atmosphere in the process chamber having a pressure that is maintained above the peak pressure during step e); and
wherein the acoustical energy is megasonic energy.

12. A method of processing a substrate comprising:
a) supporting a substrate in a substantially horizontal orientation in a process chamber;
b) applying a film of liquid to at least one surface of the substrate;
c) positioning a transmitter so that at least a portion of the transmitter is in contact with the film of liquid, the transmitter operably coupled to a transducer;
d) creating a gaseous atmosphere in the process chamber having a pressure;
e) generating acoustical energy with the transducer having a substantially sinusoidal waveform;
f) transmitting the acoustical energy to the film of liquid via the transmitter;
g) determining a peak pressure exerted on the film of liquid that corresponds to the peak amplitude of the acoustical energy; and
wherein the pressure of the gaseous atmosphere is maintained above the peak pressure during step f).

13. The method of claim 12 wherein the film of liquid is not subjected to a negative pressure during step f).

14. The method of claim 12 wherein the acoustical energy is megasonic energy.

15. The method of claim 12 wherein the transmitter comprises an elongate forward portion that is in contact with the film of liquid.

16. The method of claim 12 wherein the transmitter comprises an elongated edge that is in contact with the film of liquid.

17. The method of claim 12 wherein step c) comprises positioning the transmitter close to but spaced from the surface of the substrate upon which the film of liquid is applied.

18. A system for processing a substrate comprising:
a process chamber having a gaseous atmosphere;
a support for supporting a substrate in a substantially horizontal orientation within the gaseous atmosphere of the process chamber;
means for applying a film of liquid to a surface of a substrate positioned on the support;
a transmitter adapted to be positioned in contact with the film of liquid applied to the surface of the substrate;
a transducer operably coupled to the transmitter and adapted to generate acoustical energy having a sinusoidal waveform having a peak amplitude, the peak amplitude corresponding to a peak pressure exerted to the film of liquid;
means for pressurizing the gaseous atmosphere to a pressure that is greater than the peak pressure.

19. The system of claim 18 further comprising means for maintaining the pressure of the gaseous atmosphere greater than the peak pressure during application of acoustical energy to the substrate.

20. The system of claim 18 wherein the transmitter comprises an elongate forward portion in contact with the film of the liquid or an elongate edge in contact with the film of the liquid.
